(19) United States
(12) Patent Application Publication
(10) Pub. No.: US 2012/0154060 A1
(43) Pub. Date: Jun. 21, 2012

(54) QUADRATURE VOLTAGE-CONTROLLED OSCILLATOR APPARATUS

(75) Inventors: Chih-Hsiang Chang, Taichung City (TW); Jung-Mao Lin, Taichung City (TW); Ching-Yuan Yang, Taichung City (TW)

(73) Assignee: INDUSTRIAL TECHNOLOGY RESEARCH INSTITUTE, Hsinchu (TW)

(21) Appl. No.: 13/018,378

(22) Filed: Jan. 31, 2011

(30) Foreign Application Priority Data
Dec. 20, 2010 (TW) 99144816

(51) Int. Cl. H03B 5/12

(52) U.S. Cl. 331/56

(57) ABSTRACT

A quadrature voltage-controlled oscillator (QVCO) apparatus including a first VCO, a second VCO, a first energy-storage element, a second energy-storage element, a third energy-storage element and a fourth energy-storage element is provided. The first VCO has a first and a second phase output ends. The second VCO has a third and a fourth phase output ends. A first and a second ends of the first energy-storage element respectively connect to the first and the third phase output ends. A first and a second ends of the second energy-storage element respectively connect to the second and the third phase output ends. A first and a second ends of the third energy-storage element respectively connect to the second and the fourth phase output ends. A first and a second ends of the fourth energy-storage element respectively connect to the first and the fourth phase output ends.

### CROSS-REFERENCE TO RELATED APPLICATION

This application claims the priority benefit of Taiwan application serial no. 99144816, filed on Dec. 20, 2010. The entirety of the above-mentioned patent application is hereby incorporated by reference herein and made a part of this specification.

### BACKGROUND

1. Field of the Disclosure

The disclosure relates to an oscillator. Particularly, the disclosure relates to a quadrature voltage-controlled oscillator apparatus.

2. Description of Related Art

Many modern cable/wireless transmission structures use a quadrature voltage-controlled oscillator (QVCO) to generate an in-phase (I) and a quadrature-phase (Q) clock signals for performing modulation and demodulation. It is very difficult for a general QVCO to simultaneously have a good phase-noise level and an accurate phase difference while operating in a high-frequency circuit. Therefore, wireless transmission circuits developed by major manufacturers can only be designed in allusion to specifications of a single nation. Namely, the general QVCO cannot simultaneously satisfy the wireless transmission specifications of all nations.

### SUMMARY OF THE DISCLOSURE

The disclosure provides a quadrature voltage-controlled oscillator (QVCO) apparatus including a first voltage-controlled oscillator (VCO), a second VCO, a first energy-storage element, a second energy-storage element, a third energy-storage element and a fourth energy-storage element. The first VCO has a first phase output end and a second phase output end. The second VCO has a third phase output end and a fourth phase output end. A first end and a second end of the first energy-storage element are respectively connected to the first phase output end and the third phase output end. A first end and a second end of the second energy-storage element are respectively connected to the second phase output end and the third phase output end. A first end and a second end of the third energy-storage element are respectively connected to the second phase output end and the fourth phase output end. A first end and a second end of the fourth energy-storage element are respectively connected to the first phase output end and the fourth phase output end.

According to the above descriptions, in the disclosure, the first to the fourth energy-storage elements are used to mutually check/restrain the first to the fourth phase output ends. Therefore, the QVCO apparatus of the disclosure can accurately output signals with a phase difference of 90 degrees, and can ameliorate the phase-noise level. Moreover, compared to the conventional structure, area cost of the QVCO apparatus of the disclosure is not high. The QVCO apparatus of the disclosure satisfies a low-voltage application environment and a high frequency design requirement, so that it is adapted to all wireless transmission specifications in the market.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a functional block schematic diagram of a quadrature voltage-controlled oscillator (QVCO) apparatus according to an exemplary embodiment of the disclosure.

FIG. 2 is a circuit schematic diagram of the QVCO apparatus of FIG. 1 according to an exemplary embodiment of the disclosure.

FIG. 3 is schematic diagram illustrating an equivalent circuit of the QVCO apparatus of FIG. 2 according to an exemplary embodiment of the disclosure.

FIG. 4 is a diagram of a measurement result of phase output ends IP and QP of the QVCO apparatus of FIG. 2 according to an exemplary embodiment of the disclosure.

FIG. 5 is a phase-noise curve diagram of the QVCO apparatus of FIG. 2 according to an exemplary embodiment of the disclosure.

FIG. 6 is a circuit schematic diagram of the QVCO apparatus of FIG. 1 according to another exemplary embodiment of the disclosure.

FIG. 7 is a circuit schematic diagram of the QVCO apparatus of FIG. 1 according to still another exemplary embodiment of the disclosure.

FIG. 8 is a circuit schematic diagram of the QVCO apparatus of FIG. 1 according to yet another exemplary embodiment of the disclosure.

FIG. 9 is a circuit schematic diagram of the QVCO apparatus of FIG. 1 according to yet another exemplary embodiment of the disclosure.

### DETAILED DESCRIPTION OF DISCLOSED EMBODIMENTS

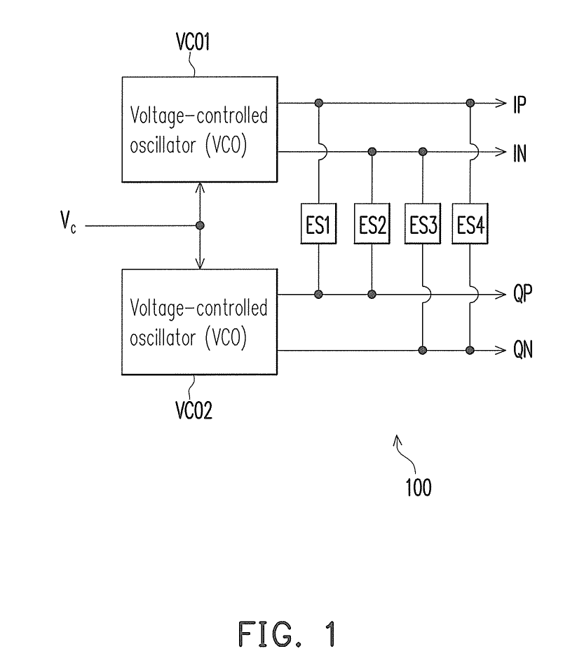

FIG. 1 is a functional block schematic diagram of a quadrature voltage-controlled oscillator (QVCO) apparatus 100 according to an exemplary embodiment of the disclosure. The QVCO apparatus 100 includes a first voltage-controlled oscillator (VCO) VCO1, a second VCO VCO2, a first energy-storage element ES1, a second energy-storage element ES2, a third energy-storage element ES3 and a fourth energy-storage element ES4. The first VCO VCO1 and the second VCO VCO2 can be any type of a two-phase voltage-controlled oscillator. Circuit structures of the first VCO VCO1 and the second VCO VCO2 can be the same of different. The first VCO VCO1 has a first phase output end IP and a second phase output end IN. The phase output ends IP and IN of the first VCO VCO1 can respectively provide two clock signals inverted to each other (with a phase difference of 180⁰). Moreover, the second VCO VCO2 has a third phase output end QP and a fourth phase output end QN. Clock signals output by the phase output ends QP and QN of the second VCO VCO2 are inverted to each other (with a phase difference of 180°). According to a level of a control voltage Vc, the first VCO VCO1 and the second VCO VCO2 respectively adjust clock frequencies of the phase output ends IP, IN, QP and QN.

A first end and a second end of the first energy-storage element ES1 are respectively connected to the first phase output end IP and the third phase output end QP. A first end and a second end of the second energy-storage element ES2 are respectively connected to the second phase output end IN and the third phase output end QP. A first end and a second end of the third energy-storage element ES3 are respectively connected to the second phase output end IN and the fourth phase output end QN. A first end and a second end of the fourth energy-storage element ES4 are respectively connected to the first phase output end IP and the fourth phase output end QN. The energy-storage elements ES1-ES4 can temporarily store electric energy. For example, capacitive elements can be used to implement the energy-storage elements ES1-ES4 to temporarily store charges (or voltage). For another example, inductive elements can be used to implement the energy-storage elements ES1-ES4 to temporarily store currents. The energy-storage elements ES1-ES4 are used to mutually check/restrain the phase output ends IP, IN, QP and QN. Therefore, the phase output ends IP and IN can respectively provide two in-phase clock signals inverted to each other, and the phase output ends QP and QN can respectively provide two quadrature-phase clock signals inverted to each other.

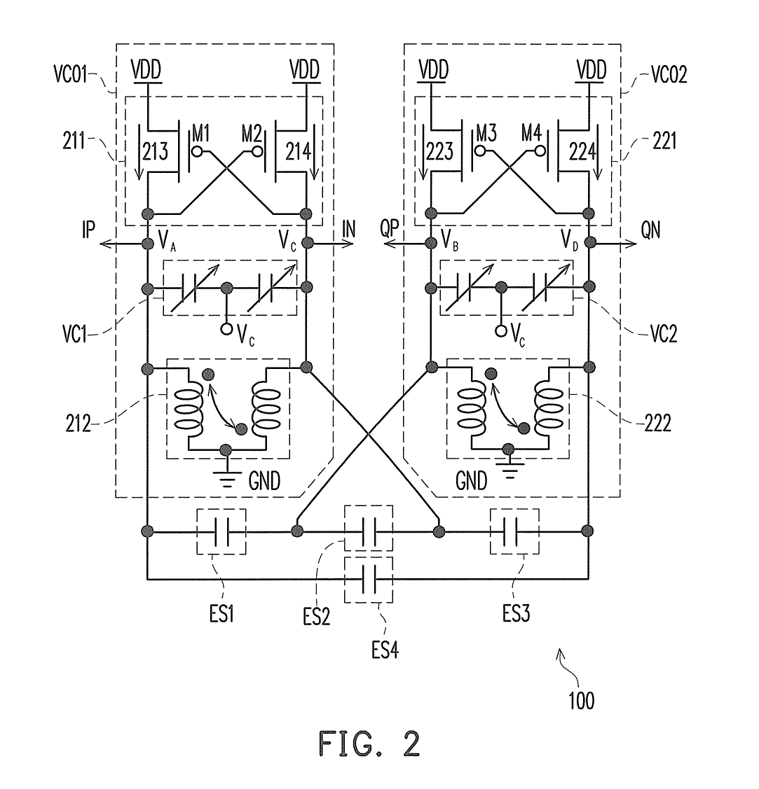

FIG. 2 is a circuit schematic diagram of the QVCO apparatus 100 of FIG. 1 according to an exemplary embodiment of the disclosure. Referring to related descriptions of FIG. 1, in the present exemplary embodiment, the capacitive elements are used to implement the energy-storage elements ES1-ES4, where capacitances of these capacitive elements are substantially the same. In the present exemplary embodiment, the capacitive elements can be implemented through any approaches, for example, distributed capacitors, metal-insulator-metal (MIM) capacitors, or metal oxide semiconductor (MOS) capacitors, etc. Alternatively, in other embodiments, a combination of a plurality of elements can be used to form an equivalent capacitor, and the equivalent capacitor can be used to implement these energy-storage elements ES1-ES4.

Referring to FIG. 2, the first VCO VCO1 of the present exemplary embodiment includes a first variable capacitor VC1, a first negative resistance circuit 211 and a first transformer 212. A first end and a second end of the first variable capacitor VC1 are respectively connected to the first phase output end IP and the second phase output end IN of the first VCO VCO1, where the control voltage Vc can change a capacitance of the first variable capacitor VC1. The first negative resistance circuit 211 has a first current path 213 and a second current path 214, where a first end of the first current path 213 and a first end of the second current path 214 are respectively connected to the first end and the second end of the first variable capacitor VC1, and a second end of the first current path 213 and a second end of the second current path 214 are connected to a first voltage. The first voltage can be any fixed reference voltage, and in the present exemplary embodiment, the first voltage is a system voltage VDD.

In FIG. 2, an implementation of the first negative resistance circuit 211 is illustrated, though the disclosure is not limited thereto. The first negative resistance circuit 211 includes a first transistor M1 and a second transistor M2. In the present exemplary embodiment, the first transistor M1 and the second transistor M2 are all P-channel metal oxide semiconductor (PMOS) transistors. A first end and a second end (for example, a drain and a source) of the first transistor M1 respectively serve as the first end and the second end of the first current path 213. A first end and a second end (for example, a drain and a source) of the second transistor M2 respectively serve as the first end and the second end of the second current path 214. The first end of the second transistor M2 is coupled to a control end (for example, a gate) of the first transistor M1, and a control end (for example, a gate) of the second transistor M2 is coupled to the first end of the first transistor M1.

The first transformer 212 has a primary coil and a secondary coil. A first end of the primary coil of the first transformer 212 is connected to the first end of the first current path 213, a first end of the secondary coil of the first transformer 212 is connected to the first end of the second current path 214, and a second end of the primary coil and a second end of the secondary coil of the first transformer 212 are connected to a second voltage. The second voltage can be any fixed reference voltage, and in the present exemplary embodiment, the second voltage is a ground voltage GND.

Similar to the first VCO VCO1, the second VCO VCO2 includes a second variable capacitor VC2, a second negative resistance circuit 221 and a second transformer 222. A first end and a second end of the second variable capacitor VC2 are respectively connected to the third phase output end QP and the fourth phase output end QN of the second VCO VCO2. The second negative resistance circuit 221 has a third current path 223 and a fourth current path 224, where a first end of the third current path 223 and a first end of the fourth current path 224 are respectively connected to the first end and the second end of the second variable capacitor VC2, and a second end of the third current path 223 and a second end of the fourth current path 224 are connected to the first voltage (the system voltage VDD).

Similar to the first negative resistance circuit 211, the second negative resistance circuit 221 includes a third transistor M3 and a fourth transistor M4. In the present exemplary embodiment, the third transistor M3 and the fourth transistor M4 are all PMOS transistors. A first end and a second end (for example, a drain and a source) of the third transistor M3 respectively serve as the first end and the second end of the third current path 223. A first end and a second end (for example, a drain and a source) of the fourth transistor M4 respectively serve as the first end and the second end of the fourth current path 224. The first end of the fourth transistor M4 is coupled to a control end (for example, a gate) of the third transistor M3, and a control end (for example, a gate) of the fourth transistor M4 is coupled to the first end of the third transistor M3.

The second transformer 222 has a primary coil and a secondary coil. A first end of the primary coil of the second transformer 222 is connected to the first end of the third current path 223, a first end of the secondary coil of the second transformer 222 is connected to the first end of the fourth current path 224, and a second end of the primary coil and a second end of the secondary coil of the second transformer 222 are connected to the second voltage (the ground voltage GND).

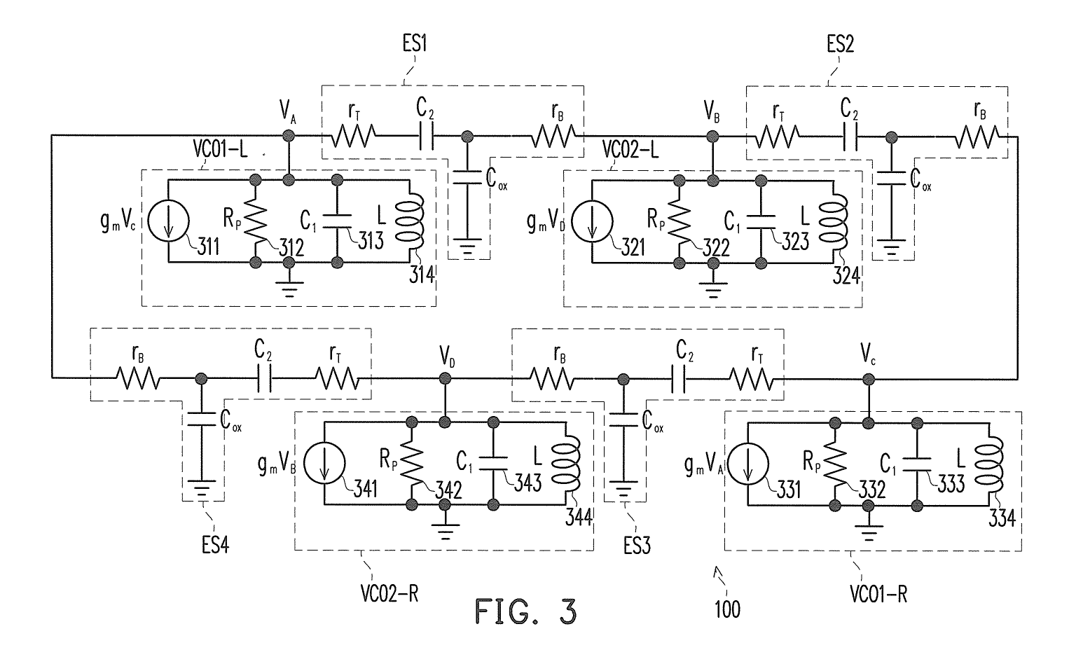

FIG. 3 is schematic diagram illustrating an equivalent circuit of the QVCO apparatus 100 of FIG. 2 according to an exemplary embodiment of the disclosure. In FIG. 3, voltages V_{A}, V_{B}, V_{c} and V_{D} respectively represent voltages of the phase output ends IP, QP, IN and QN shown in FIG. 2. A left half circuit (the transistor M1, the variable capacitor VC1, the primary coil of the transformer 212, etc.) of the first VCO VCO1 of FIG. 2 can be equivalent to an equivalent circuit VCO1-L of FIG. 3. The equivalent circuit VCO1-L includes an equivalent current source 311, an equivalent resistor 312, an equivalent capacitor 313 and an equivalent inductor 314, where a current value of the equivalent current source 311 relates to a product of a conductance gₘ of the transistor M1 and the voltage V_{c} of the phase output terminal IN, i.e. gₘ×V_{c}. A left half circuit (the transistor M3, the variable capacitor VC2, the primary coil of the transformer 222, etc.) of the second VCO VCO2 of FIG. 2 can be equivalent to an equivalent circuit VCO2-L of FIG. 3. The equivalent circuit VCO2-L includes an equivalent current source 321, an equivalent resistor 322, an equivalent capacitor 323 and an equivalent inductor 324, where a current value of the equivalent current source 321 relates to a product of a conductance gₘ of the transistor M3 and the voltage V_{D} of the phase output terminal QN, i.e. gₘ×V_{D}. A right half circuit (the transistor M2, the variable capacitor VC1, the secondary coil of the transformer 212, etc.) of the first VCO VCO1 of FIG. 2 can be equivalent to an equivalent circuit VCO1-R of FIG. 3. The equivalent circuit VCO1-R includes an equivalent current source 331, an equivalent resistor 332, an equivalent capacitor 333 and an equivalent inductor 334, where a current value of the equivalent current source 331 relates to a product of a conductance gₘ of the transistor M2 and the voltage V_{A} of the phase output terminal IP, i.e. gₘ×V_{A}. A right half circuit (the transistor M4, the variable capacitor VC2, the secondary coil of the transformer 222, etc.) of the second VCO VCO2 of FIG. 2 can be equivalent to an equivalent circuit VCO2-R of FIG. 3. The equivalent circuit VCO2-R includes an equivalent current source 341, an equivalent resistor 342, an equivalent capacitor 343 and an equivalent inductor 344, where a current value of the equivalent current source 341 relates to a product of a conductance gₘ of the transistor M4 and the voltage V_{B} of the phase output terminal QP, i.e. gₘ×V_{B}. Moreover, a resistance of the equivalent resistors 312, 322, 332 and 342 is R_{P}, a capacitance of the equivalent capacitors 313, 323, 333 and 343 is C₁, and an inductance of the equivalent inductors 314, 324, 334 and 344 is L.

Equivalent circuits of the energy-storage elements ES1-ES4 of FIG. 2 are as that shown in FIG. 3. The equivalent circuits of the energy-storage elements ES1-ES4 respectively include an equivalent resistor r_{T}, an equivalent resistor r_{B}, an equivalent capacitor C₂ and an equivalent capacitor C_{OX}. By analysing the equivalent circuit of FIG. 3, an output frequency w₀ thereof is shown as a following equation 1, where γ in the equation 1 is represented by an equation 2. If the equivalent capacitance C₁ is 1 pF, and the equivalent inductance L is 1.4 nH, the output frequency wₒ is then 5.5 GHz.

$${ω}_{0}^{2} = \frac{- γ + \sqrt{{γ}^{2} + 4 {{C}_{1} ( {r}_{T} {C}_{2} )}^{2} L}}{2 {{C}_{1} ( {r}_{T} {C}_{2} )}^{2} L} \qquad Equation 1$$

γ=C₁L+2C₂L−(r_{T}C₂)² Equation 2

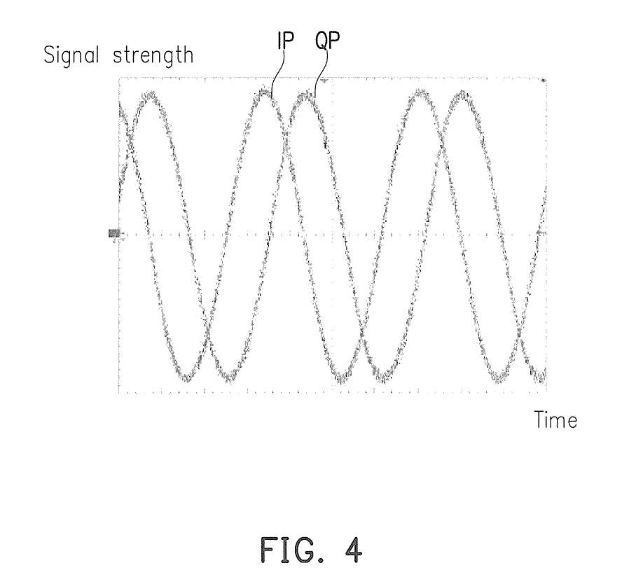

Here, a standard 0.18 μm complementary metal-oxide semiconductor (CMOS) fabrication process is used to implement the QVCO apparatus 100 shown in FIG. 2. FIG. 4 is a diagram of a measurement result of the phase output ends IP and QP of the QVCO apparatus 100 of FIG. 2 according to an exemplary embodiment of the disclosure. In FIG. 4, a vertical axis represents signal strength, and a horizontal axis represents time. Here, the system voltage VDD is 0.6V. When an adjustment range of the control voltage Vc is 0-VDD, an output frequency range of the phase output terminal (for example, IP or OP) is 5.29-5.67 GHz, and power consumption is about 5.2 mW.

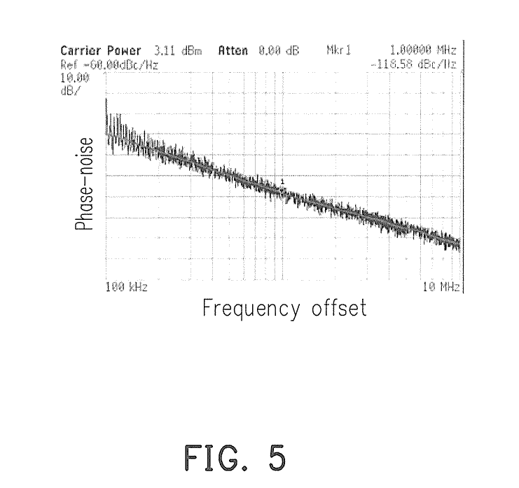

FIG. 5 is a phase-noise curve diagram of the QVCO apparatus 100 of FIG. 2 according to an exemplary embodiment of the disclosure. In FIG. 5, a vertical axis represents the phase-noise, and a horizontal axis represents frequency offsets. FIG. 5 illustrates the phase-noise of the QVCO apparatus 100 at a central band (for example, 5.48-GHz) of the output frequency range when the output power is 3.1 dBm. A mark “1” in FIG. 5 represents the phase-noise of the QVCO apparatus 100 of FIG. 2 is about −118.58 dBc/Hz in case of the frequency offset of 1-MHz,

According to the above descriptions, the first to the fourth energy-storage elements ES1-ES4 are used to mutually check/restrain the first to the fourth phase output ends, so that the phase output terminals IP, IN, QP and QN of the QVCO apparatus 100 can accurately output signals with a phase difference of 90 degrees, and the phase-noise level can be ameliorated. Moreover, compared to the conventional structure, the QVCO structure 100 of the present exemplary embodiment is adapted to a low-voltage circuit design, and area cost thereof is not high. The QVCO apparatus 100 of the present exemplary embodiment satisfies a low-voltage application environment and a high-frequency design requirement, so that it is adapted to all wireless transmission specifications in the market. Moreover, compared to transistors, the capacitors of the energy-storage elements ES1-ES4 can reduce interferences of thermal noises, and are less susceptible to the effects of process variations.

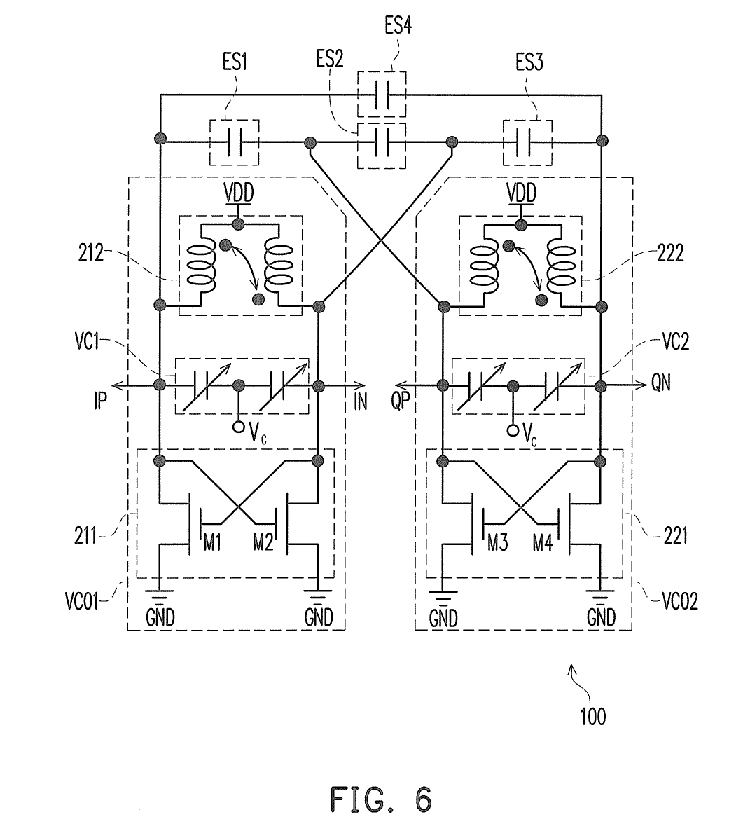

The first VCO VCO1 and the second VCO VCO2 can also be implemented through other methods. For example, FIG. 6 is a circuit schematic diagram of the QVCO apparatus 100 of FIG. 1 according to another exemplary embodiment of the disclosure. Related descriptions of FIG. 1 and FIG. 2 can be referred for the exemplary embodiment of FIG. 6. Different to the embodiment of FIG. 2, in the present exemplary embodiment of FIG. 6, the first transistor M1, the second transistor M2, the third transistor M3 and the fourth transistor M4 are all N-channel metal oxide semiconductor (NMOS) transistors. Moreover, the first voltage connected to a source of the first transistor M1 (the second end of the first current path), a source of the second transistor M2 (the second end of the second current path), a source of the third transistor M3 (the second end of the third current path) and a source of the fourth transistor M4 (the second end of the fourth current path) is the ground voltage GND, and the second voltage connected to the second ends of the primary coil and the secondary coil of the first transformer 212 and the second ends of the primary coil and the secondary coil of the second transformer 222 is the system voltage VDD.

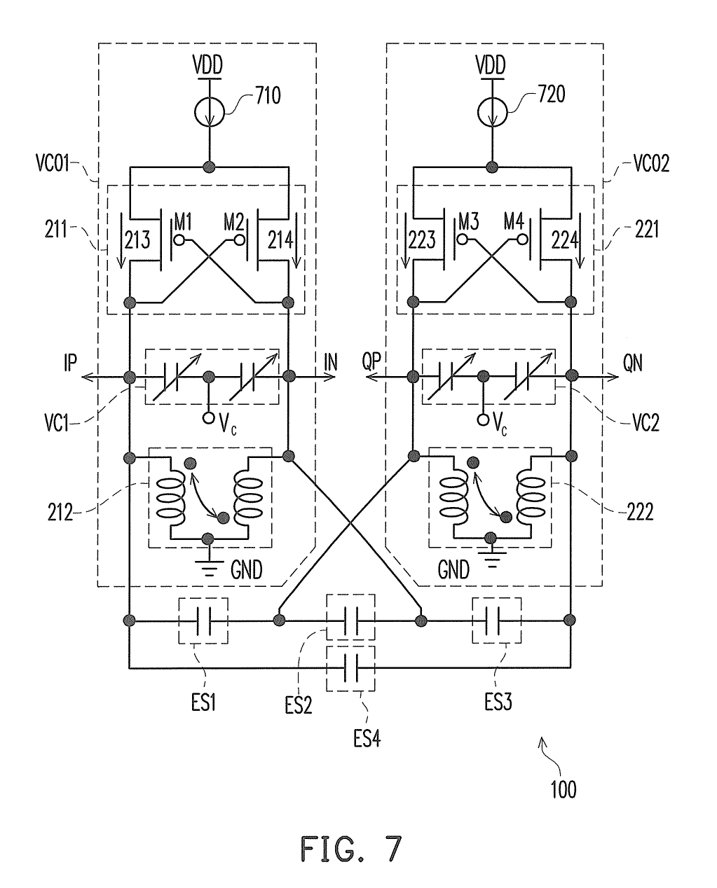

FIG. 7 is a circuit schematic diagram of the QVCO apparatus 100 of FIG. 1 according to still another exemplary embodiment of the disclosure. Related descriptions of FIG. 1 and FIG. 2 can be referred for the exemplary embodiment of FIG. 7. Different to the embodiment of FIG. 2, in the present exemplary embodiment of FIG. 7, the first VCO VCO1 further includes a first current source 710, and the second VCO VCO2 further includes a third current source 720. A first end of the first current source 710 is connected to the source of the transistor M1 (the second end of the first current path) and the source of the transistor M2 (the second end of the second current path). A first end of the third current source 720 is connected to the source of the transistor M3 (the second end of the third current path) and the source of the transistor M4 (the second end of the fourth current path). Second ends of the first current source 710 and the third current source 720 are connected to the first voltage (for example, the system voltage VDD).

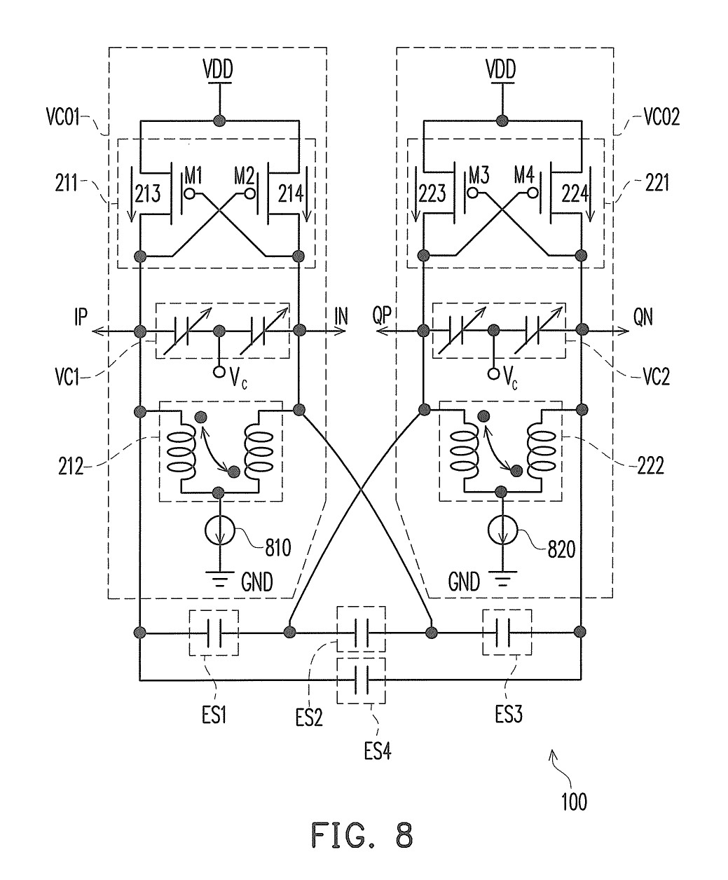

FIG. 8 is a circuit schematic diagram of the QVCO apparatus 100 of FIG. 1 according to yet another exemplary embodiment of the disclosure. Related descriptions of FIG. 1 and FIG. 2 can be referred for the exemplary embodiment of FIG. 8. Different to the embodiment of FIG. 2, in the present exemplary embodiment of FIG. 8, the first VCO VCO1 further includes a second current source 810, and the second VCO VCO2 further includes a fourth current source 820. A first end of the second current source 810 is connected to the second ends of the primary coil and the secondary coil of the first transformer 212. A first end of the fourth current source 820 is connected to the second ends of the primary coil and the secondary coil of the second transformer 222. Second ends of the second current source 810 and the fourth current source 820 are connected to the second voltage (for example, the ground voltage GND).

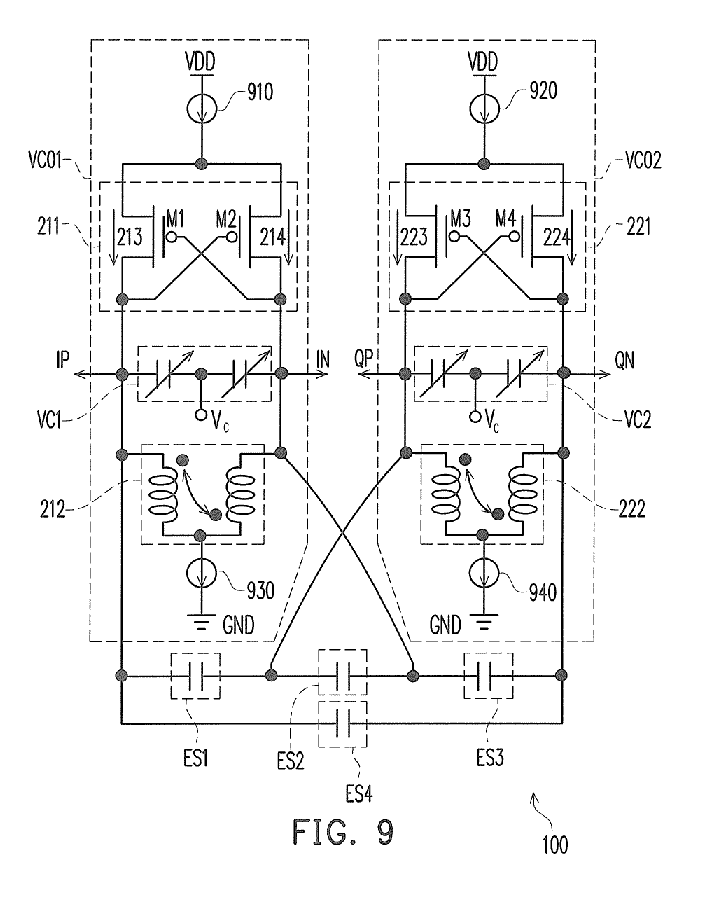

FIG. 9 is a circuit schematic diagram of the QVCO apparatus 100 of FIG. 1 according to yet another exemplary embodiment of the disclosure. Related descriptions of FIG. 1 and FIG. 2 can be referred for the exemplary embodiment of FIG. 9. Different to the embodiment of FIG. 2, in the present exemplary embodiment of FIG. 9, the first VCO VCO1 further includes a first current source 910 and a second current source 930, and the second VCO VCO2 further includes a third current source 920 and a fourth current source 940. A first end of the first current source 910 is connected to the source of the transistor M1 (the second end of the first current path) and the source of the transistor M2 (the second end of the second current path). A first end of the third current source 920 is connected to the source of the transistor M3 (the second end of the third current path) and the source of the transistor M4 (the second end of the fourth current path). Second ends of the first current source 910 and the third current source 920 are connected to the first voltage (for example, the system voltage VDD). A first end of the second current source 930 is connected to the second ends of the primary coil and the secondary coil of the first transformer 212. A first end of the fourth current source 940 is connected to the second ends of the primary coil and the secondary coil of the second transformer 222. Second ends of the second current source 930 and the fourth current source 940 are connected to the second voltage (for example, the ground voltage GND).

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A quadrature voltage-controlled oscillator (QVCO) apparatus, comprising:
a first voltage-controlled oscillator (VCO), having a first phase output end and a second phase output end;
a second VCO, having a third phase output end and a fourth phase output end;
a first energy-storage element, having a first end and a second end respectively connected to the first phase output end and the third phase output end;
a second energy-storage element, having a first end and a second end respectively connected to the second phase output end and the third phase output end;
a third energy-storage element, having a first end and a second end respectively connected to the second phase output end and the fourth phase output end; and
a fourth energy-storage element, having a first end and a second end respectively connected to the first phase output end and the fourth phase output end.

2. The QVCO apparatus as claimed in claim 1, wherein the first energy-storage element, the second energy-storage element, the third energy-storage element and the fourth energy-storage element are capacitive elements.

3. The QVCO apparatus as claimed in claim 1, wherein the first energy-storage element, the second energy-storage element, the third energy-storage element and the fourth energy-storage element are inductive elements.

4. The QVCO apparatus as claimed in claim 1, wherein the first VCO comprises:
a first variable capacitor, having a first end and a second end respectively connected to the first phase output end and the second phase output end;
a first negative resistance circuit, having a first current path and a second current path, wherein a first end of the first current path and a first end of the second current path are respectively connected to the first end and the second end of the first variable capacitor; and
a first transformer, having a primary coil and a secondary coil, wherein a first end of the primary coil of the first transformer is connected to the first end of the first current path, and a first end of the secondary coil of the first transformer is connected to the first end of the second current path.

5. The QVCO apparatus as claimed in claim 4, wherein a second end of the first current path and a second end of the second current path are connected to a first voltage, and a second end of the primary coil and a second end of the secondary coil of the first transformer are connected to a second voltage.

6. The QVCO apparatus as claimed in claim 5, wherein the first voltage is a system voltage, and the second voltage is a ground voltage.

7. The QVCO apparatus as claimed in claim 5, wherein the first voltage is a ground voltage, and the second voltage is a system voltage.

8. The QVCO apparatus as claimed in claim 4, wherein the first VCO further comprises:
a first current source, connected to a second end of the first current path and a second end of the second current path,
wherein second ends of the primary coil and the secondary coil of the first transformer are connected to a second voltage.

9. The QVCO apparatus as claimed in claim 4, wherein the first VCO further comprises:
a second current source, connected to second ends of the primary coil and the secondary coil of the first transformer,
wherein a second end of the first current path and a second end of the second current path are connected to a first voltage.

10. The QVCO apparatus as claimed in claim 4, wherein the first VCO further comprises:
a first current source, connected to a second end of the first current path and a second end of the second current path; and
a second current source, connected to second ends of the primary coil and the secondary coil of the first transformer.

11. The QVCO apparatus as claimed in claim 4, wherein the first negative resistance circuit comprises:
a first transistor, having a first end and a second end respectively serving as the first end and a second end of the first current path; and
a second transistor, having a first end and a second end respectively serving as the first end and a second end of the second current path, wherein the first end and a control end of the second transistor are respectively coupled to a control end and the first end of the first transistor.

12. The QVCO apparatus as claimed in claim 4, wherein the second VCO comprises:
a second variable capacitor, having a first end and a second end respectively connected to the third phase output end and the fourth phase output end;
a second negative resistance circuit, having a third current path and a fourth current path, wherein a first end of the third current path and a first end of the fourth current path are respectively connected to the first end and the second end of the second variable capacitor; and
a second transformer, having a primary coil and a secondary coil, wherein a first end of the primary coil of the second transformer is connected to the first end of the third current path, and a first end of the secondary coil of the second transformer is connected to the first end of the fourth current path.

13. The QVCO apparatus as claimed in claim 12, wherein a second end of the first current path, a second end of the second current path, a second end of the third current path and a second end of the fourth current path are connected to a first voltage, and a second end of the primary coil of the first transformer, a second end of the secondary coil of the first transformer, a second end of the primary coil of the second transformer and a second end of the secondary coil of the second transformer are connected to a second voltage.

14. The QVCO apparatus as claimed in claim 13, wherein the first voltage is a system voltage, and the second voltage is a ground voltage.

15. The QVCO apparatus as claimed in claim 13, wherein the first voltage is a ground voltage, and the second voltage is a system voltage.

16. The QVCO apparatus as claimed in claim 12, wherein the first VCO comprises a first current source, the second VCO comprises a third current source; the first current source is connected to a second end of the first current path and a second end of the second current path; the third current source is connected to a second end of the third current path and a second end of the fourth current path; and a second end of the primary coil of the first transformer, a second end of the secondary coil of the first transformer, a second end of the primary coil of the second transformer and a second end of the secondary coil of the second transformer are connected to a second voltage.

17. The QVCO apparatus as claimed in claim 12, wherein the first VCO comprises a second current source, the second VCO comprises a fourth current source; the second current source is connected to second ends of the primary coil and the secondary coil of the first transformer; the fourth current source is connected to second ends of the primary coil and the secondary coil of the second transformer; and a second end of the first current path, a second end of the second current path, a second end of the third current path and a second end of the fourth current path are connected to a first voltage.

18. The QVCO apparatus as claimed in claim 12, wherein the first VCO comprises a first current source and a second current source, and the second VCO comprises a third current source and a fourth current source; the first current source is connected to a second end of the first current path and a second end of the second current path; the second current source is connected to second ends of the primary coil and the secondary coil of the first transformer; the third current source is connected to a second end of the third current path and a second end of the fourth current path; and the fourth current source is connected to second ends of the primary coil and the secondary coil of the second transformer.

19. The QVCO apparatus as claimed in claim 12, wherein the first negative resistance circuit comprises a first transistor and a second transistor, and the second negative resistance circuit comprises a third transistor and a fourth transistor; a first end and a second end of the first transistor respectively serve as the first end and a second end of the first current path; a first end and a second end of the second transistor respectively serve as the first end and a second end of the second current path; the first end and a control end of the second transistor are respectively coupled to a control end and the first end of the first transistor; a first end and a second end of the third transistor respectively serve as the first end and a second end of the third current path; a first end and a second end of the fourth transistor respectively serve as the first end and a second end of the fourth current path; the first end and a control end of the fourth transistor are respectively coupled to a control end and the first end of the third transistor.

20. The QVCO apparatus as claimed in claim 1, wherein the second VCO comprises:
a second variable capacitor, having a first end and a second end respectively connected to the third phase output end and the fourth phase output end;
a second negative resistance circuit, having a third current path and a fourth current path, wherein a first end of the third current path and a first end of the fourth current path are respectively connected to the first end and the second end of the second variable capacitor; and
a second transformer, having a primary coil and a secondary coil, wherein a first end of the primary coil of the second transformer is connected to the first end of the third current path, and a first end of the secondary coil of the second transformer is connected to the first end of the fourth current path.

21. The QVCO apparatus as claimed in claim 20, wherein a second end of the third current path and a second end of the fourth current path are connected to a first voltage, and a second end of the primary coil and a second end of the secondary coil of the second transformer is connected to a second voltage.

22. The QVCO apparatus as claimed in claim 21, wherein the first voltage is a system voltage, and the second voltage is a ground voltage.

23. The QVCO apparatus as claimed in claim 21, wherein the first voltage is a ground voltage, and the second voltage is a system voltage.

24. The QVCO apparatus as claimed in claim 20, wherein the second VCO further comprises:
a third current source, connected to a second end of the third current path and a second end of the fourth current path,
wherein second ends of the primary coil and the secondary coil of the second transformer are connected to a second voltage.

25. The QVCO apparatus as claimed in claim 20, wherein the second VCO further comprises:
a fourth current source, connected to second ends of the primary coil and the secondary coil of the second transformer,
wherein a second end of the third current path and a second end of the fourth current path are connected to a first voltage.

26. The QVCO apparatus as claimed in claim 20, wherein the second VCO further comprises:
a third current source, connected to a second end of the third current path and a second end of the fourth current path; and
a fourth current source, connected to second ends of the primary coil and the secondary coil of the second transformer.

27. The QVCO apparatus as claimed in claim 20, wherein the second negative resistance circuit comprises:
a third transistor, having a first end and a second end respectively severing as the first end and a second end of the third current path; and
a fourth transistor, having a first end and a second end respectively severing as the first end and a second end of the fourth current path, wherein the first end and a control end of the fourth transistor are respectively coupled to a control end and the first end of the third transistor.
